(19) United States
(12) Patent Application Publication
(10) Pub. No.: US 2004/0212527 A1
(43) Pub. Date: Oct. 28, 2004

(54) Method and apparatus for improving accuracy of analog to digital converters

(76) Inventor: John E. Hanna, Gilbert, AZ (US)

Correspondence Address: David D. Bahler, Esq., FULBRIGHT & JAWORSKI, L.L.P., Suite 2400, 600 Congress Avenue, Austin, TX, 78701, US

(21) Appl. No.: 10/420,090

(22) Filed: Apr. 22, 2003

(51) Int. Cl. H03M 1/12

(52) U.S. Cl. 341/155; 341/122

(57) ABSTRACT

Systems and methods are described for improving the accuracy of A/D converters. The method includes sampling an input voltage and a reference voltage substantially simultaneously, transmitting both the sampled input voltage and the sampled reference voltage to an analog-to-digital converter, and producing a digital signal based on the sampled reference voltage and the sampled input voltage. The apparatus includes first and second samplers coupled to receive a reference voltage and an input voltage and operating to sample the voltages substantially simultaneously, and an A/D converter, which receives input from the first and second samplers.

### BACKGROUND OF THE INVENTION

1. Field of the Invention

The invention relates generally to the field of analog to digital signal conversion.

2. Discussion of the Related Art

Analog-to-digital (A/D) converters are present in many electronics in use today. The need to transform an analog signal, such as a voltage, into a digital signal of 0's and 1's is part of everyday life. There are many different types of A/D converters available. They include ratiometric converters, RSD (Redundant Signed Digit) converters, sigma-delta converters, and successive approximation converters. In particular, ratiometric converters may be found commonly in the touch-screens in use today.

The measurement of electric circuit parameters, such as resistance and conductance using ratiometric techniques, is well known. Many ratiometric measurement circuits use a dual slope analog-to-digital (A/D) converter to measure the unknown value of a parameter. These A/D converters are commonly referred to as ratiometric converters when used in ratiometric measurement circuits. Ratiometric converters consume relatively small amounts of power and, hence, have found widespread use in battery powered devices, such as, for example, portable measurement instruments and are also widely used for touch screen applications like PDAs and high end cell phones.

A ratiometric converter is a converter whose output is inversely proportional to its reference voltage and directly proportional to its input voltage. That is:

V_{OUT}=k(V_{IN}/V_{REF})

where V_{OUT} is the converter output voltage, k is a numerical constant, V_{IN} is the input voltage, and V_{REF} is the reference voltage. A ratiometric analog to digital converter performs multiple comparisons with a reference voltage during the conversion process.

During a conversion, the reference voltage may vary for different reasons. In A/D converters which sample an input voltage and perform sequential comparisons with the reference voltage, this reference voltage variation reduces the accuracy of the conversion. In some applications, switched reference voltages are used. However, switched reference voltages require long settling times and, to reduce noise, the reference is usually filtered, slowing the conversion time even further.

Also, the circuit parameters to be measured may be located in “noisy” environments, such as telephone lines, for example, in which the noise exists as leakage current and/or alternating current (a/c) interference. As is well known, this may cause fluctuations in the reference voltage used in ratiometric conversions. In fact, the accuracy of a ratiometric measurement instrument depends, at least in part, on the noise rejection capability of the ratiometric measurement circuit. That is, to some degree, the better the signal-to-noise ratio of the ratiometric measurement circuit, the higher the accuracy of the measurement instrument.

Prior art ratiometric converter circuits required a tradeoff between the size of the noise reducing filter capacitors on the touch screen terminals and the time before a sample could be taken. In the prior art, the filter capacitors had to be relatively large to prevent supply noise from corrupting the reference voltage, but this undesirably increased the lag time between sampling events.

Accordingly, there is a need for a A/D conversion measurement circuit that has a minimal amount of time delay before sampling an input voltage and an improved accuracy of conversion.

### BRIEF DESCRIPTION OF THE DRAWINGS

The present invention is directed to an A/D conversion measurement circuit designed to avoid the above-noted drawbacks. The drawings accompanying and forming part of this specification are included to depict certain aspects of the invention. The invention may be better understood by reference to one or more of these drawings in combination with the description presented herein. It should be noted that the features illustrated in the drawings are not necessarily drawn to scale.

FIG. 1 is a block diagram showing the components of an A/D conversion measurement circuit, in accordance with an embodiment of the present invention.

FIG. 2 is a another block diagram illustrating an embodiment of the present invention as utilized by a touch-screen.

FIG. 3 is a timing diagram illustrating an embodiment of the present invention as utilized by a touch-screen.

FIG. 4 is a circuit diagram illustrating an embodiment of the present invention as utilized by a touch-screen.

### DETAILED DESCRIPTION

In accordance with one aspect of the invention, a method for analog to digital conversion includes sampling and holding an input voltage while substantially simultaneously sampling and holding a reference voltage, transmitting both the sampled input voltage and the sampled reference voltage to an analog-to-digital converter, and producing a digital signal based on the sampled reference voltage and the sampled input voltage.

In accordance with another aspect of the invention, an apparatus for analog-to-digital conversion includes, a first sampler coupled to receive a reference voltage and to produce a sampled reference voltage, a second sampler coupled to receive an input voltage and to produce a sampled input voltage, an analog-to-digital converter, coupled to the first and second samplers to receive the sampled reference voltage and the sampled input voltage, and a controller for controlling the first and second samplers to sample the reference voltage substantially simultaneous with the input voltage.

In accordance with yet another aspect of the invention, an apparatus for analog-to-digital conversion includes a first input voltage, a second input voltage, a first plurality of transistors coupled to the first input voltage, a second plurality of transistors coupled to the second input voltage, a first switch configured to select between the first and second plurality of transistors, a second switch configured to select between the first and second plurality of transistors, a first sampler having an input coupled to the first switch, a second sampler having an input coupled to the second switch, an A/D converter coupled to the first and second samplers, and a controller for controlling the A/D converter, the first and second samplers, and the first and second switches.

These and other features and embodiments of the invention will be better appreciated and understood when considered in conjunction with the following description and the accompanying drawings. It should be understood, however, that the following description, while indicating various embodiments of the invention and numerous specific details thereof, is given by way of illustration and not of limitation. Many substitutions, modification, additions and/or rearrangements may be made within the scope of the invention without departing from the spirit thereof, and the invention includes all such substitutions, modifications, additions and/or rearrangements.

While currently available A/D converters may possess a sample-and-hold capability, they only sample and store the input voltage, and not the reference voltage. Instead, the reference voltage is continuously sampled by the converter each time it is needed during the conversion process. Any disturbances which would cause the reference voltage to fluctuate would be reflected in the distortion of the final digital signal that is output by the A/D converter.

Substantially simultaneous sampling of the reference and input voltages, as described below, is applicable to any A/D converter that receives as input an input voltage and reference voltage. These A/D converters may include, but are not limited to, ratiometric converters, RSD converters, sigma-delta converters, and successive approximation converters.

For example, a voltage that is digitized to establish the pen position on a touch screen may be a fraction of a voltage applied across the touch screen. When a ratiometric A/D converter is used to establish the pen position, the accuracy of the measurement may be improved if the voltage across the touch screen is sampled at substantially the same time as the voltage to be converted. Similarly, when an RSD A/D converter is used to establish the pen position, the voltage applied across the screen establishes the reference voltage, and both the reference voltage and the input voltage reflect the pen position at the same point in time. Prior art A/D converters did not sample the reference voltage across the screen, only the input voltage to the converter. If the voltage across the screen changed between the time that the input voltage was sampled and the time the voltage across the screen was used in the conversion process, then the accuracy of the conversion was degraded.

FIG. 1 is a block diagram of an embodiment of the present invention. In this embodiment, sampler 110 captures an input voltage 125 and inputs it to an A/D converter 100. At substantially same time, sampler 115 captures a reference voltage 120 and inputs it to the a/d converter 100 as well. The sampled reference voltage and the sampled input voltage are then used by the A/D converter 100 to produce a digital signal N. Sampler 115 stores the sampled reference voltage until it is needed by the A/D converter 100. A controller 105 controls the processes of the A/D converter 100. By following the direction of the controller 105, the A/D converter may dictate to the samplers 110, 115 when to sample their respective voltages. The samplers 110, 115 may comprise a switch coupled to a capacitor to form controllable sample and hold circuits, where the capacitor may store the sampled voltage of the sampler. Other types of samplers may also be acceptable.

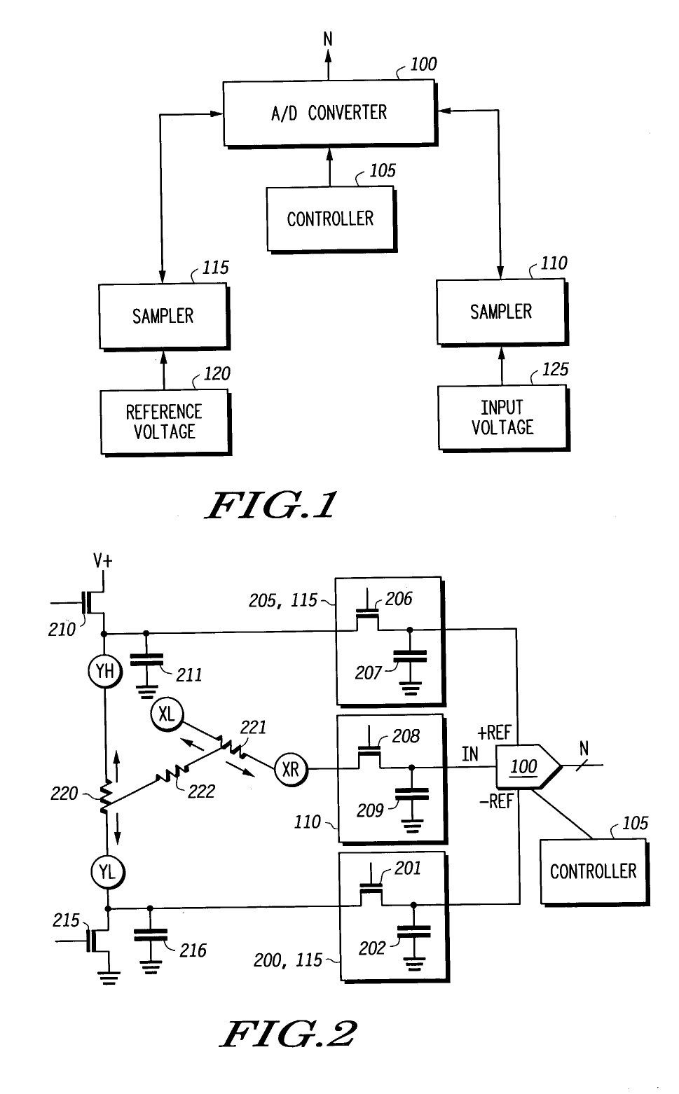

FIG. 2 illustrates a more detailed block diagram of an embodiment of the invention. This embodiment may utilize a ratiometric A/D converter 100 and may be used to determine the XY position of a pen on a touch-screen. The touch screen may be included in, for example, a cell phone, a PDA and/or a computer screen. In FIG. 2, only certain electrical components are illustrated in order to improve clarity. In particular, FIG. 2 shows the configuration of components necessary to sense the pen position on the touch screen in the Y direction. The operation of all components necessary for sensing the pen position in the X direction will be explained but they are not completely illustrated in FIG. 2.

In FIG. 2, transistor 210 is coupled to V⁺ and to a Y-plane resistance 220, which is used to measure the vertical distance of a pen touch on the touch screen. The YH end of the Y-plane resistance 220 denotes the highest vertical position on the touch screen. Transistor 215 is coupled to ground and to the Y-plane resistance 220 at the YL end of the Y-plane resistance 220. The YL end of the Y-plane resistance 220 denotes the lowest vertical position on the touch screen. Capacitor 211 is coupled to ground and is also coupled to the YH end of Y-plane resistance 220 to transistor 210. Similarly, capacitor 216 is coupled to ground and is also coupled to the YL end of Y-plane resistance 220 and to transistor 215.

X-plane resistance 221 is the resistance across the touch screen as measured from the left point, XL, to the right point XR, on the touch screen. X-plane resistance 221 is used to measure the horizontal distance of a pen touch on the touch screen. The XL end of the X-plane resistance 221 denotes the left-most horizontal position on the touch screen, and the XR end of the X-plane resistance 221 denotes the right-most horizontal position on the touch screen.

In a touch screen application, the X-plane resistance 221 and the Y-plane resistance 220 are located on two separate layers. The contact of a pen or other pointing object on the screen creates a contact between these two layers which is represented in FIG. 2 as resistance 222. This resistance 222 represents a connection resistance between the X-plane and the Y-plane at the location of the point where contact is made, thus coupling a fraction of the total Y-plane voltage that appears at the press point to the X-plane resistance 221. During calculation of the pen's position on the touch screen, resistance 221 serves to couple the voltage from resistor 222 to sampler 110.

In this illustration, the XR end of X-plane resistance 221 is coupled to sampler 110, which comprises transistor 208 and capacitor 209, and XL end of X-plane resistance 221 is unconnected. Sampler 110 is coupled to the input IN of an A/D converter 100. Sampler 110 is shown here to be separate from the A/D converter 100 for ease of description. However, sampler 110 may be implemented as the built-in sampler in an A/D converter, if the built-in sampler has a sample-and-hold function.

The A/D converter 100 also has two additional inputs labeled +REF and −REF. The +REF input is coupled to receive the output of sampler 205, which comprises transistor 206 and capacitor 207, and the −REF input is coupled to receive the output of sampler 200, which comprises transistor 201 and capacitor 202. Samplers 200, 205 are equivalent to the sampler 115 shown in FIG. 1. The functions of the A/D converter 100 and samplers 110, 200, 205 are directed by a controller 105.

To determine the position of a pen on the touch screen, the X and Y coordinates are calculated separately. To calculate the Y coordinates, transistors 210, 215 are turned on and the YH end of Y-plane resistance 220 is connected to V+ and the YL end of Y-plane resistance 220 is connected to V−. Current passes through the total Y-plane resistance 220, and the fraction of the total voltage across resistor 220 at the press point is measured and passed through to sampler 110. In this case, resistance 222 couples terminal XR to the point on the Y-axis at which the pen is pressed against the touch screen. At substantially the same time that the voltage across resistance 220 is being sampled by sampler 110, samplers 205, 200 sample the reference voltage +REF and −REF, which is the voltage across the Y-plane resistance.

To calculate the X coordinates, and using components that are not illustrated in FIG. 2, the YH end of the Y-plane resistance 220 is disconnected from V+ and the XL end of X-plane resistance 221 is connected to V+. Similarly, the YL end of Y-plane resistance 220 is disconnected from V− and the XR end of X-plane resistance 221 is connected to V−. In addition, the XR end of X-plane resistance 221 is disconnected from sampler 110, and the YH end of Y-plane resistance 220 is connected to the input of sampler 110. Then, the fraction of the voltage across resistance 221 that appears at the press point is sampled by sampler 110. In this case, resistance 222 couples the voltage on resistor 221 from the point at which the pen is pressed against the touch screen to the Y-plane resistance 220. Again, at substantially the same time that the fraction of the voltage across resistance 221 is being sampled by sampler 110, samplers 205, 200 sample the reference voltage +REF and −REF, which is the voltage across the X-plane resistance. This will be shown in more detail in FIG. 4.

In short, when X coordinates are to be measured, the resistance 222 couples the fraction of the voltage from the press point on the Y-plane resistance 220. When Y coordinates are to be measured, the resistance 222 couples the fraction of the voltage from the press point on the X-plane resistance 221. Once the A/D converter 100 receives analog input from the samplers 110, 200, 205, it processes the information and outputs a digital signal N to produce the XY coordinates of the pen position.

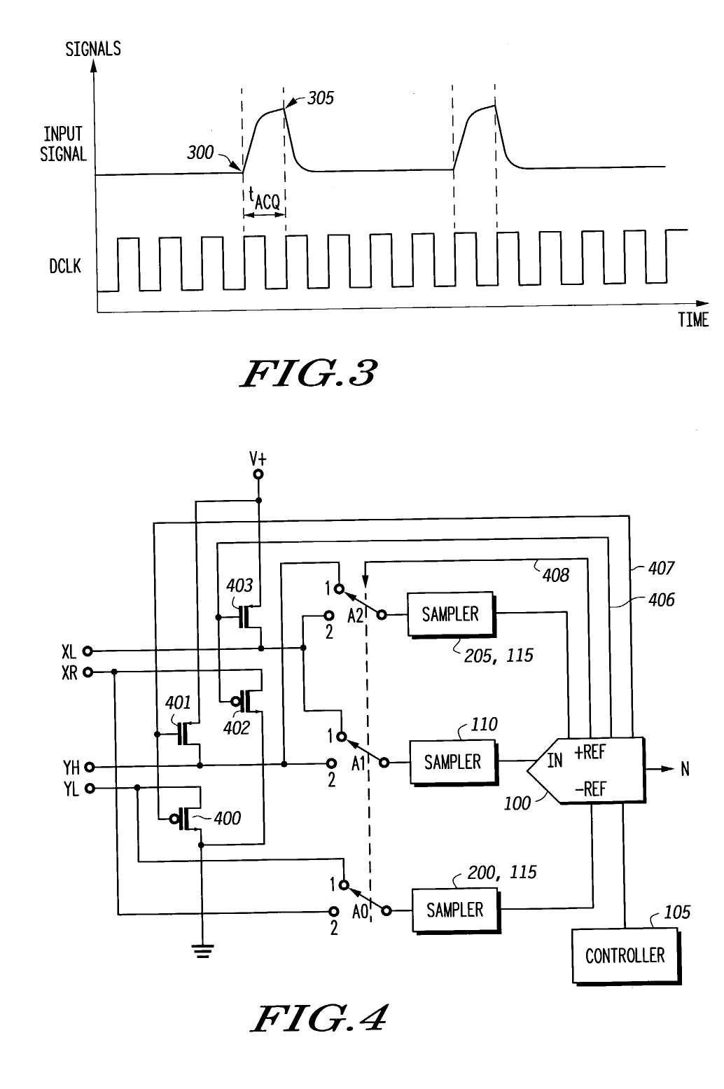

FIG. 3 shows a timing diagram for the embodiment of the invention shown in FIG. 2. In FIG. 3, an input voltage is shown relative to a digital clock signal DCLK. t_{ACQ} is the time lapse between the time when the signal is produced and when the signal may be accurately sampled. The t_{ACQ} begins at point 300 on the signal and ends at point 305, when the signal has reached a maximum level. In the prior art, t_{ACQ} may be 4 or more times longer than shown here due to the capacitors used to reduce noise related fluctuations of the reference voltage, which also affects the sampling time of the input voltage. By sampling the reference voltage at the same time as the input voltage according to an embodiment of the invention, the need for capacitors to reduce noise-related reference voltage fluctuations is eliminated. Without the capacitors, t_{ACQ} may be much shorter, which results in a shorter sampling lag time and a fast overall process.

In a 10-bit A/D converter 100 with a 2 mV resolution, a 4 mV change in a 2V reference can produce a 1 lsb (least significant bit) error in a mid-scale value of a digital output that is produced. This is 0.2% of the reference voltage, implying that, in the case of a switched reference voltage, such as the one shown in FIG. 2, more than 6.2 time constants are need to settle before sampling can occur. The time constant may be determined by factors such as sampling capacitors and switches. By sampling both the input and the reference substantially simultaneously, this may be reduced to 2 to 3 time constants. Since noise on the reference is common to both input and reference, the time constant may be reduced or eliminated.

In prior art systems, the touch screen must remain powered for the duration of the conversion (i.e. for as long as the reference voltage is needed). In addition, this screen power is typically ten times the power consumption of the A/D converter. By using the present invention, the reference voltage may be sampled much more quickly and the screen may be powered down after the reference voltage is sampled. As a result, the average power may be reduced by a factor of about 5.

FIG. 4 is a second and more detailed circuit implementation of the present invention as used for a touch screen as shown in FIG. 2. Once again, the touch screem may be incorporated in a cell phone, PDA, computer screen, or any type of electrical device. XL, XR, YH, and YL are the inputs of the circuit, corresponding with the four output terminals of the touch screen. XL is coupled to transistor 403 and controllable switch A2. Switch A2 is also coupled to switches A1 and control line 408, while transistor 403 is coupled to V⁺, the A/D converter 100, and is controlled by control line 406.

XL is coupled to switches A1 and A2 and transistor 403. XR is coupled to transistor 402 and switch to A0. Transistor 402 is coupled to ground, and transistor 400. Transistor 400 is coupled to transistor 401 and ground. Transistor 401 is coupled to the A/D converter 100 and to V⁺.

YH is coupled to switch A1, and transistor 401. YL is coupled to transistor 400 and switch A0. Switch A1 is also coupled to a sampler 110 that is coupled to the input IN of the A/D converter 100. Switch A1 is coupled to and controlled by control line 408. Switch A0 is coupled to sampler 200 that is coupled to the negative reference input −REF of the A/D converter 100. Switch A0 is coupled to and controlled by control line 408. Switch A2 is also coupled to a sampler 205 that is coupled to the positive reference input +REF of the A/D converter 100. Switch A2 is also coupled to and controlled by control line 408. A/D converter 100 also receives input from a controller 105 which controls the functions of the A/D converter 100 including when to send signals to the samplers 110, 200, 205 to sample their respective voltages. The A/D converter 100 also sends control signals 406, 407 to transistors 400-403 to turn them on or off, and a control signal 408 to switches A0-A2 to set them at either position 1 or position 2.

Similar to the function of the circuit shown in FIG. 2, the circuit of FIG. 4 may use a ratiometric A/D converter and may be used to decode a pen position on a touch-screen. Again, X and Y coordinates of the pen's position are determined separately. As before, sampler 110 may be implemented as the built-in sampler in an A/D converter, if the built-in sampler has a sample-and-hold function, and need not be a separate sampler as is shown in the present diagram.

To obtain the Y-coordinates of the pen position, switches A0-A2, which are ganged (in the same position at the same time) are set in position 1. The A/D converter 100 turns transistors 400, 401 on via signal 407, and turns transistors 402-403 off, via signal 406. Therefore, samplers 200, 205 read their respective reference voltage values as the voltages at YH and YL, or the voltage across the resistor between YH and YL in FIG. 2. At substantially the same time, sampler 110 samples its input. This input to sampler 110 is the voltage of the XL input, which is a fraction of the voltage across resistance 220 in the Y direction. The samplers output their voltages to the A/D converter 100, which then outputs a digital signal N.

To obtain the X-coordinates of the pen position, switches A0-A2 are set in position 2. The A/D controller 100 turns transistors 402, 403 on via signal 406, and turns transistors 400-401 off, via signal 407. Therefore, samplers 200, 205 read their respective reference voltage values as the voltages at XL and XR, or the voltage across the resistor between XR and XL in FIG. 2. At substantially the same time, sampler 110 samples its input. This input to sampler 110 is the voltage of the YH input, which is the fractional voltage across resistance 221 in the X direction. The samplers then output their voltages to the A/D converter 100, which then outputs a digital signal N.

The terms a or an, as used herein, are defined as one or more than one. The term plurality, as used herein, is defined as two or more than two. The term another, as used herein, is defined as at least a second or more. The terms including and/or having, as used herein, are defined as comprising (i.e., open language). The term coupled, as used herein, is defined as connected, although not necessarily directly, and not necessarily mechanically. The term substantially, as used herein, is defined as at least approaching a given state (e.g., preferably within 10% of, more preferably within 1% of, and most preferably within 0.1% of).

The appended claims are not to be interpreted as including means-plus-function limitations, unless such a limitation is explicitly recited in a given claim using the phrase(s) “means for” and/or “step for.” Subgeneric embodiments of the invention are delineated by the appended independent claims and their equivalents. Specific embodiments of the invention are differentiated by the appended dependent claims and their equivalents.

1. A method for analog to digital conversion, comprising:
sampling and storing an input voltage to produce a sampled and stored input voltage;
sampling and storing a reference voltage, substantially simultaneously with the sampling of the input voltage, to produce a sampled and stored reference voltage; and
producing a digital output signal as a function of the sampled and stored input voltage and the sampled and stored reference voltage.

2. (canceled)

3. (canceled)

4. (canceled)

5. The method of claim 1, where the digital output signal is a analog to digital conversion of a ratio of the sampled and stored input voltage and the sampled and stored reference voltage.

6. An apparatus for analog-to-digital conversion, comprising:
a first sample and hold unit coupled to receive a reference voltage and to produce a sampled reference voltage;
a second sample and hold unit coupled to receive an input voltage and to produce a sampled input voltage;
an analog-to-digital converter, coupled to the first and second and hold units to receive the sampled reference voltage and the sampled input voltage; and
a controller for controlling the first and second sample and hold units to sample and hold the reference voltage substantially simultaneous with the input voltage.

7. The apparatus of claim 6, where the first sample and hold unit comprises a controllable switch and a capacitor.

8. The apparatus of claim 6, where the second sample and hold unit is built into the analog-to-digital converter.

9. The apparatus of claim 6, the controller being coupled to the analog-to-digital converter to control the analog-to-digital converter to process the sampled reference voltage and the sampled input voltage after the reference voltage and the input voltage have been sampled.

10. The apparatus of claim 6, the analog-to-digital converter selected from the group consisting of, a ratiometric converter, redundant signed digit converter, sigma-delta converter, and a successive approximation converter.

11. An electronic apparatus comprising:
a first sample and hold unit configured to receive an input voltage;
a second sample and hold unit configured to receive a reference voltage;
an analog-to-digital converter, which receives input from the first sample and hold unit and the second sample and hold unit; and
a controller, for controlling the analog-to-digital converter and the first and second sample and hold units to sample and hold the input and reference voltages substantially simultaneously and to produce a digital output signal as a function of the sampled input and reference voltages.

12. The electronic apparatus of claim 11, further comprising a touch screen that provides the input and reference voltages.

13. The electronic apparatus of claim 12, wherein the electronic apparatus is a cell phone.

14. The electronic apparatus of claim 12, wherein the electronic apparatus is a personal digital assistant.

15. The electronic apparatus of claim 12, wherein the electronic apparatus is a computer screen.

16. An apparatus for analog-to-digital conversion, comprising:
a first plurality of transistors coupled to receive a first input voltage;
a second plurality of transistors coupled to receive a second input voltage;
a first sample and hold unit having an input coupled to the first plurality of transistors;
a second sample and hold unit having an input coupled to the second plurality of transistors;
an converter, coupled to receive input from the first and second samplers; and
a controller for controlling the converter, the first and second samplers, and the first and second plurality of transistors.

17. The apparatus of claim 16, where the first and second plurality of transistors are not on at the same time.

18. The apparatus of claim 16, where the first sample and hold unit comprises a switch and a capacitor coupled together in series.

19. The apparatus of claim 16, where the second sample and hold unit is built into the analog-to-digital converter.

20. The apparatus of claim 16, the analog-to-digital converter being selected from the group consisting of, a ratiometric converter, redundant signed digit converter, sigma-delta converter, and successive approximation converter.
